(19) United States
(12) Patent Application Publication
(10) Pub. No.: US 2016/0013301 A1
(43) Pub. Date: Jan. 14, 2016

(54) SEMICONDUCTOR DEVICE AND METHOD OF MANUFACTURING THE SAME

(71) Applicant: Nuvoton Technology Corporation, Hsinchu (TW)

(72) Inventor: MD Imran SIDDIQUI, Hsinchu (TW)

(21) Appl. No.: 14/327,623

(22) Filed: Jul. 10, 2014

(51) Int. Cl. H01L 29/739; H01L 29/66; H01L 21/225; H01L 21/265; H01L 29/10; H01L 29/423; H01L 29/08

(52) U.S. Cl. CPC H01L 29/7397; H01L 29/4236; H01L 29/66348; H01L 29/0847; H01L 21/26513; H01L 29/0821; H01L 29/1095; H01L 21/2253

(57) ABSTRACT

The semiconductor device includes a first semiconductor layer of a first conductivity type, an insulated gate structure, a first semiconductor region of a second conductivity type, a second semiconductor region of the first conductivity type, and a lightly doped semiconductor region of the second conductivity type. The insulated gate structure is formed in a trench configuration recessed into the first semiconductor layer. The first semiconductor region, the second semiconductor region, and the lightly doped semiconductor region are formed in the first semiconductor layer. The second semiconductor region contacts the first semiconductor region and the insulated gate structure. The second semiconductor region is formed on the lightly doped semiconductor region. The lightly doped semiconductor region is formed between and contacts the first semiconductor region and the insulated gate structure. A method of manufacturing a semiconductor device is also disclosed herein.

### BACKGROUND

1. Technical Field

The present disclosure relates to a semiconductor device. More particularly, embodiments of the present disclosure relates to a semiconductor device including an insulated gate structure.

2. Description of Related Art

High-power switching devices are gradually required in various applications. Accordingly, various semiconductor devices have been developed to accommodate large currents and/or high voltages which are needed in the high-power switching devices. The aforementioned semiconductor devices also provide various levels of performance for parameters of interest, such as forward voltage drop V_{FD} and safe-operating-area (SOA), in which SOA is defined as a current-voltage boundary within which a power switching device can be operated without failure. For example, an insulated-gate bipolar transistor (IGBT) is one of the aforementioned semiconductor devices.

However, although various kinds of present IGBTs have been developed, the present IGBTs have large leakage currents. In addition, leakage current issues in the present IGBTs also result in a poor forward biased safe operating area (FBSOA) and a poor short circuit safe operating area (SCSOA). As a result, the present IGBTs still cannot provide good performance when they are applied as high-power switching devices.

### SUMMARY

An aspect of the present disclosure is related to a semiconductor device. The semiconductor device includes a first semiconductor layer of a first conductivity type, an insulated gate structure, a first semiconductor region of a second conductivity type, a second semiconductor region of the first conductivity type, and a lightly doped semiconductor region of the second conductivity type. The insulated gate structure is formed in a trench configuration recessed into the first semiconductor layer. The first semiconductor region is formed in the first semiconductor layer. The second semiconductor region is formed in the first semiconductor layer, and the second semiconductor region contacts the first semiconductor region and the insulated gate structure. The lightly doped semiconductor region is formed in the first semiconductor layer. The second semiconductor region is formed on the lightly doped semiconductor region. The lightly doped semiconductor region is formed between and contacts the first semiconductor region and the insulated gate structure.

Another aspect of the present disclosure is related to a semiconductor device. The semiconductor device includes a P-type collector layer, an N-type drift layer, an insulated gate structure, a first P-type heavily doped region, an N-type heavily doped region and a P-type lightly doped region. The N-type drift layer is formed above the P-type collector layer. The insulated gate structure is formed in a trench configuration recessed into the N-type drift layer. The first P-type heavily doped region is formed in the N-type drift layer. The N-type heavily doped region is formed in the N-type drift layer, and the N-type heavily doped region contacts the first P-type heavily doped region and the insulated gate structure. The P-type lightly doped region is formed in the N-type drift layer, and the P-type lightly doped region contacts the insulated gate structure, the first P-type heavily doped region and the N-type heavily doped region.

Still another aspect of the present disclosure is related to a method of manufacturing a semiconductor device. The method includes operations of: forming an N-type drift layer; forming an insulated gate structure in a trench configuration recessed into the N-type drift layer; forming a first P-type heavily doped region formed in the N-type drift layer; forming a P-type lightly doped region in the N-type drift layer, in which the P-type lightly doped region contacts the insulated gate structure and the first P-type heavily doped region; and forming an N-type heavily doped region on the P-type lightly doped region in the N-type drift layer, in which the N-type heavily doped region contacts the first P-type heavily doped region and the insulated gate structure.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of various embodiments, with reference to the accompanying drawings as follows:

FIG. 1 is a schematic diagram of a semiconductor device according to some embodiments of the present disclosure;

FIG. 2 is a schematic diagram of a leakage current corresponding to a forward voltage drop of the semiconductor device illustrated in FIG. 1, according to some embodiments of the present disclosure;

FIG. 3 is a schematic diagram of a semiconductor device according to some other embodiments of the present disclosure; and

FIG. 4 is a flow chart of a method of manufacturing a semiconductor device according to some embodiments of the present disclosure.

### DETAILED DESCRIPTION

In the following description, specific details are presented to provide a thorough understanding of the embodiments of the present disclosure. Persons of ordinary skill in the art will recognize, however, that the present disclosure can be practiced without one or more of the specific details, or in combination with other components. Well-known implementations or operations are not shown or described in detail to avoid obscuring aspects of various embodiments of the present disclosure.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

As used herein, “around”, “about”, “approximately” or “substantially” shall generally refer to any approximately values of a given value or range, in which varied depending on various arts in which it pertains, and the scope of which should be accorded with the broadest interpretation understood by the person skilled in the art to which it pertains, so as to encompass all such modifications and similar structures. In some embodiments, it mean within 20 percent, preferably within 10 percent, and more preferably within 5 percent of a given value or range. Numerical quantities given herein are approximate, meaning that the term “around”, “about”, “approximately” or “substantially” can be inferred if not expressly stated, or meaning other approximate values.

It will be understood that in the present disclosure, although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. As used herein, the term “and/or” includes any and all combinations of one or more of the associated listed items.

As used herein, the terms “comprising,” “including,” “having,” “containing,” “involving,” and the like are to be understood to be open-ended, i.e., to mean including but not limited to.

Reference throughout the specification to “one embodiment” or “an embodiment” means that a particular feature, structure, implementation, or characteristic described in connection with the embodiment is included in at least one embodiment of the present disclosure. Thus, uses of the phrases “in one embodiment” or “in an embodiment” in various places throughout the specification are not necessarily all referring to the same embodiment. Furthermore, the particular features, structures, implementation, or characteristics may be combined in any suitable manner in one or more embodiments.

In the following description and claims, the terms “coupled” and “connected”, along with their derivatives, may be used. In particular embodiments, “connected” and “coupled” may be used to indicate that two or more elements are in direct physical or electrical contact with each other, or may also mean that two or more elements may be in indirect contact with each other. “Coupled” and “connected” may still be used to indicate that two or more elements cooperate or interact with each other.

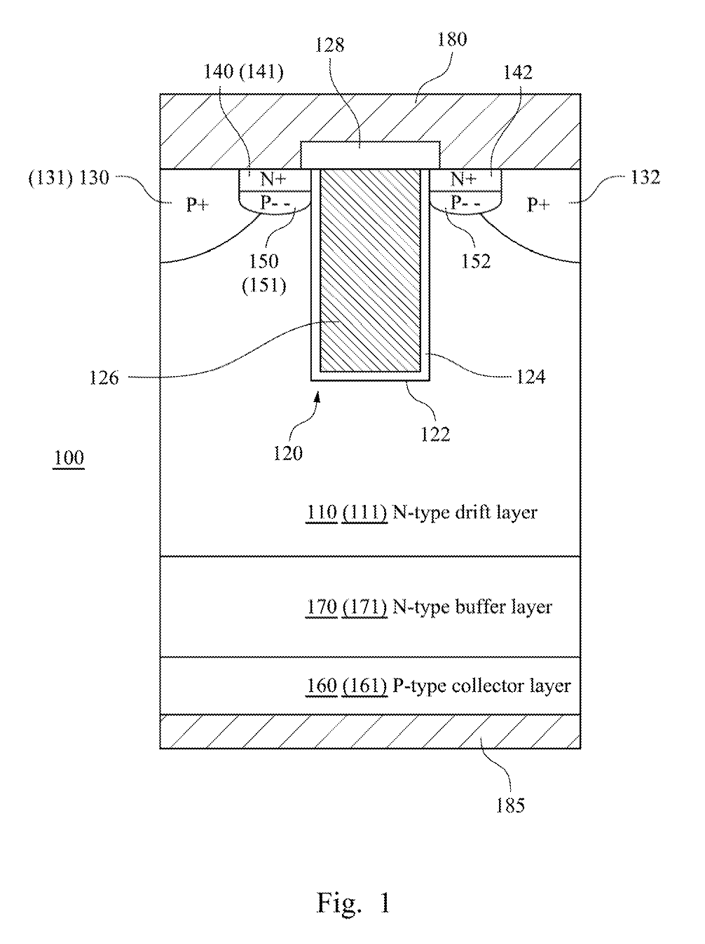

FIG. 1 is a schematic diagram of a semiconductor device according to some embodiments of the present disclosure. As illustrated in FIG. 1, the semiconductor device 100 includes a first semiconductor layer 110 of a first conductivity type, an insulated gate structure 120, a first semiconductor region 130 of a second conductivity type, a second semiconductor region 140 of the first conductivity type, and a lightly doped semiconductor region 150 of the second conductivity type. The insulated gate structure 120 is formed in a trench configuration recessed into the first semiconductor layer 110. The first semiconductor region 130 is formed in the first semiconductor layer 110. The second semiconductor region 140 is formed in the first semiconductor layer 110, and the second semiconductor region 140 contacts the first semiconductor region 130 and the insulated gate structure 120; in some embodiments, the second semiconductor region 140 is formed between and contacts the first semiconductor region 130 and the insulated gate structure 120. The lightly doped semiconductor region 150 is formed in the first semiconductor layer 110. The second semiconductor region 140 is formed in the lightly doped semiconductor region 150. The lightly doped semiconductor region 150 is formed between and contacts the first semiconductor region 130 and the insulated gate structure 120, in which the description that a semiconductor region (e.g. the lightly doped semiconductor region 150 or the second semiconductor region 140 described in specification) is formed between the first semiconductor region 130 and the insulated gate structure 120 can mean that the such semiconductor region laterally formed between the first semiconductor region 130 and the insulated gate structure 120, and thus, even if the first semiconductor region 130 and such semiconductor region are partially overlapped (e.g.; the first semiconductor region 130 and lightly doped semiconductor region 150 are partially overlapped, as illustrated in FIG. 1), such semiconductor region still can be considered as being formed between the first semiconductor region 130 and the insulated gate structure 120. Explained in a different way, the description that such semiconductor region is formed between the first semiconductor region 130 and the insulated gate structure 120 can include various structures that such semiconductor region is formed between the first semiconductor region 130 and the insulated gate structure 120 in the lateral direction.

In some embodiments, the insulated gate structure 120 may be formed by following operations. First, a trench 122 is formed. An insulating film 124 is formed over an internal wall surface of the trench 122. Then, a gate electrode 126 is formed in the trench 122. Afterwards, an interlayer dielectric (ILD) 128 is formed on the gate electrode 126.

In some embodiments, the semiconductor device 100 may further include a second semiconductor layer 160 of the second conductivity type and a third semiconductor layer 170 of the first conductivity type. The third semiconductor layer 170 is formed between the first semiconductor layer 110 and the second semiconductor layer 160. The third semiconductor layer 170 has a dopant concentration higher than that of the first semiconductor layer 110.

For illustration in FIG. 1, in some embodiments, the first semiconductor layer 110 can be an N-type drift layer 111, the first semiconductor region 130 can be a P-type heavily doped (P+) region 131, the second semiconductor region 140 can be an N-type heavily doped (N+) region 141 and the lightly doped semiconductor region 150 can be a P-type lightly doped (P−−) region 151. The insulated gate structure 120 is formed in the trench configuration recessed into the N-type drift layer 111. The P-type heavily doped region 131 is formed in the N-type drift layer 111. The N-type heavily doped region 141 is formed in the N-type drift layer 111 and the N-type heavily doped region 141 contacts the P-type heavily doped region 131 and the insulated gate structure 120; in some embodiments, the N-type heavily doped region 141 is formed between and contacts the P-type heavily doped region 131 and the insulated gate structure 120. The P-type lightly doped region 151 is formed in the N-type drift layer 111 and formed between the P-type heavily doped region 131 and the insulated gate structure 120. The N-type heavily doped region 141 is formed in the P-type lightly doped region 151. The P-type lightly doped region 151 contacts the insulated gate structure 120, the P-type heavily doped region 131 and the N-type heavily doped region 141.

In some embodiments, the P-type heavily doped region 131 is a P+ diffusion region, and the P+ diffusion region is formed by implanting a P-type dopant into a region in the N-type drift layer 111, and is formed by diffusing the region with the P-type dopant.

On the other hand, in some embodiments, the second semiconductor layer 160 can be a P-type collector layer (e.g., a P+ collector) 161, and the third semiconductor layer 170 can be an N-type buffer layer 171. The N-type drift layer 111 is formed above the P-type collector layer 161. The N-type buffer layer 171 is formed between the P-type collector layer 161 and the N-type drift layer 111.

In some embodiments, as illustrated in FIG. 1, the semiconductor device 100 may further include semiconductor regions symmetric to the aforementioned regions. The semiconductor device 100 may further include a P-type heavily doped (P+) region 132, an N-type heavily doped (N+) region 142 and a P-type lightly doped (P−−) region 152. The P-type heavily doped region 132 is formed in the N-type drift layer 111. The N-type heavily doped region 142 is formed in the N-type drift layer 111, and the N-type heavily doped region 142 contacts the P-type heavily doped region 132 and the insulated gate structure 120; in some embodiments, the N-type heavily doped region 142 is formed between and contacts the P-type heavily doped region 132 and the insulated gate structure 120. The P-type lightly doped region 152 is formed in the N-type drift layer 111 and formed between the P-type heavily doped region 132 and the insulated gate structure 120. The N-type heavily doped region 142 is formed in the P-type lightly doped region 152. The P-type lightly doped region 152 contacts the insulated gate structure 120, the P-type heavily doped region 132 and the N-type heavily doped region 142.

In further embodiments, the semiconductor device 100 is an insulated-gate bipolar transistor (IGBT), and the semiconductor device 100 may further include an emitter electrode 180 and a collector electrode 185. The emitter electrode 180 is provided as an emitter terminal of the IGBT, and the collector electrode 185 is provided as a collector terminal of the IGBT. The emitter electrode 180 is formed over a part of the surface of the N-type heavily doped regions 141 and 142 and the interlayer dielectric 128. The collector electrode 185 is formed on a back surface of the P-type collector layer 161.

By employing the structures in the semiconductor device 100, the leakage current of the semiconductor device 100 can be reduced while an optimum forward voltage drop of the semiconductor device 100 can be obtained. As a result, a forward biased safe operating area (FBSOA) of the semiconductor device 100 can be improved, and a latch-up effect can be reduced as well.

In addition, due to the introduction of the lightly doped semiconductor region 150 (e.g., the P-type lightly doped region 151), electron injection in a channel accumulation region near the N-type heavily doped region 141 is reduced. Explained in a different way, hole injection in the channel accumulation region near the N-type heavily doped region 141 can be controlled by employing the lightly doped semiconductor region 150 (e.g., the P-type lightly doped region 151). As a result, a short circuit safe operating area (SCSOA) of the semiconductor device 100, which is poor due to a higher electron concentration in the channel accumulation region, can be improved.

Moreover, the lightly doped semiconductor region 150 (e.g., the P-type lightly doped region 151) and the second semiconductor region 140 (e.g., the N-type heavily doped region 141) can be formed employing a same mask in the fabrication process. As a result, no additional mask is required. Thus, compared to conventional approaches, the structure of the semiconductor device 100 is simpler and more inexpensive for fabrication, while the semiconductor device 100 has a more improved electrical performance.

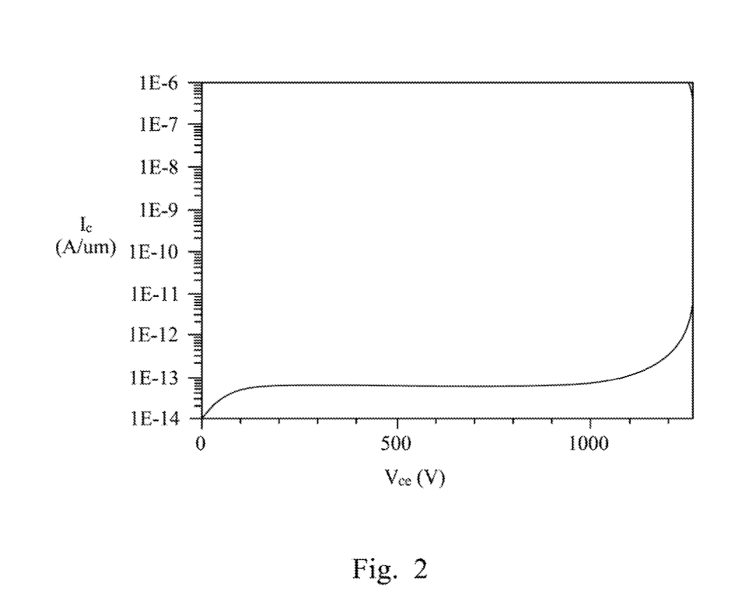

Furthermore, FIG. 2 is a schematic diagram of a leakage current corresponding to a forward voltage drop of the semiconductor device illustrated in FIG. 1 according to some embodiments of the present disclosure. As illustrated in FIG. 2, the leakage current Ic of the semiconductor device 100 is still kept very low while the forward voltage drop Vce of the semiconductor device 100 increases, by employing the structures in the semiconductor device 100.

The P-type and N-type semiconductor layers and regions mentioned above are given for purposes of illustration, and are not limiting of the present disclosure. Various P-type and N-type semiconductor layers and regions can be employed according to practical needs, and are also within the contemplated scope of the present disclosure.

In some embodiments, the P-type lightly doped region 151 has a depth within a range of approximately 0.5-2 um (micron meter), and has a width within a range of approximately 0.35-0.95 um. In other embodiments, the P-type heavily doped region 131 has a depth within a range of approximately 2.5-4.5 um. The depth of the P-type heavily doped region 131 is larger than the depth of the P-type lightly doped region 151. In other embodiments, the depth of the P-type heavily doped region 131 can be varied depending on the depth of the insulated gate structure 120.

Furthermore, in some embodiments, the lightly doped semiconductor region 150 and the second semiconductor region 140 have a substantially same width. For illustration, the P-type lightly doped region 151 and the N-type heavily doped region 141 have a substantially same width.

In some embodiments, the lightly doped semiconductor region 150 and the first semiconductor region 130 are individual semiconductor regions, and the lightly doped semiconductor region 150 has a dopant concentration lower than that of the first semiconductor region 130. For illustration, the P-type lightly doped region 151 and the P-type heavily doped region 131 are separately formed by implantation, and the P-type lightly doped region 151 has a dopant concentration lower than that of the P-type heavily doped region 131. In further embodiments, the doping concentration of the P-type lightly doped region 151 has a range of approximately 1×10¹³-1×10¹⁸ 1/cm³, and in other embodiments, this range can have ±10% of the given value.

In various embodiments, the lightly doped semiconductor region 150 is diffusively formed from the first semiconductor region 130. For illustration, the P-type heavily doped region 131 is first formed by implantation. Then, the P-type heavily doped region 131 is diffused, and the P-type lightly doped region 151 is diffusively formed from the P-type heavily doped region 131. In other words, the P-type lightly doped region 151 and the P-type heavily doped region 131 can be considered as a single region.

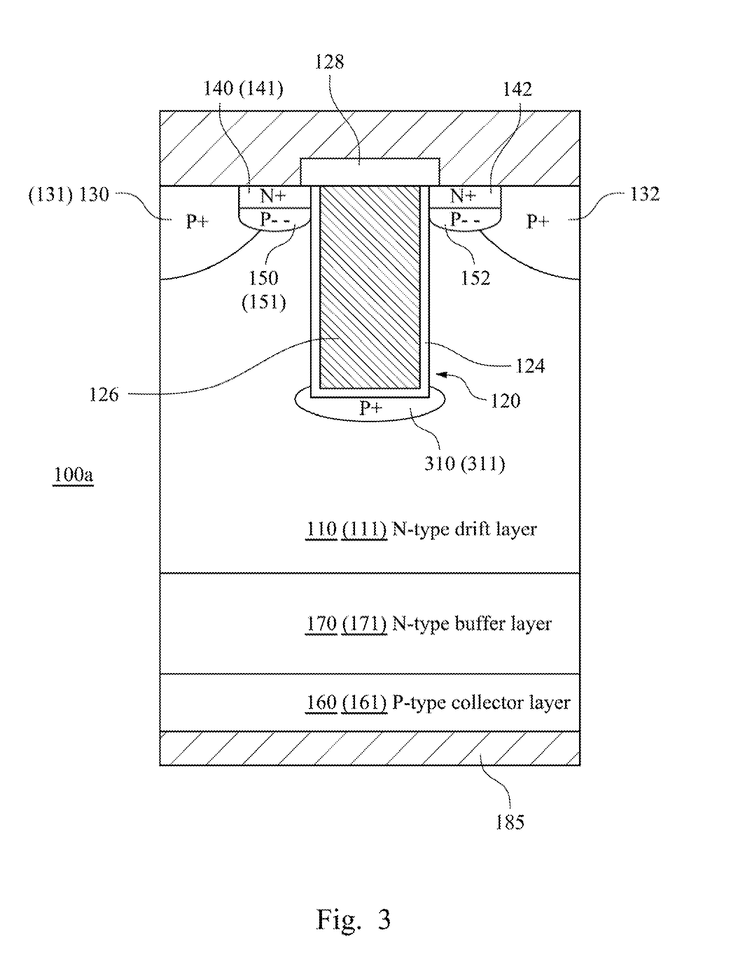

FIG. 3 is a schematic diagram of a semiconductor device according to some other embodiments of the present disclosure. Compared with the semiconductor device 100 illustrated in FIG. 1, the semiconductor device 100a in FIG. 3 may further include a third semiconductor region 310 of the second conductivity type formed in the first semiconductor layer 110. The third semiconductor region 310 contacts a bottom of the insulated gate structure 120. For illustration, the third semiconductor region 310 can be a P-type heavily doped (P+) region 311. The P-type heavily doped region 311 is formed in the N-type drift layer 111. The P-type heavily doped region 311 contacts a bottom of the insulated gate structure 120.

The P-type heavily doped region 311 is also indicated as a floating P region. The ions implanted into the P-type heavily doped region 311 should be adequate to allow a peak electric field to be present in the P-type heavily doped region 311, and not in the trench oxide (e.g., the insulating film 124). By employing the P-type heavily doped region 311, the trench oxide is protected from high peak electric fields generated when the semiconductor device 100a is reverse-biased.

In various embodiments, the P-type heavily doped region 311 is formed wide enough to span at corners of the oxide in the insulated gate structure 120 (where the trench's oxide sidewalls meet its oxide bottom). As a result, the oxide corners which are susceptible to premature breakdown can be adequately protected, and a higher forward breakdown voltage can be obtained. Moreover, due to the introduction of the P-type heavily doped region 311, a smaller saturation current level and an improved short circuit safe operating area (SCSOA) of the semiconductor device 100a can be obtained while a low forward voltage drop is maintained.

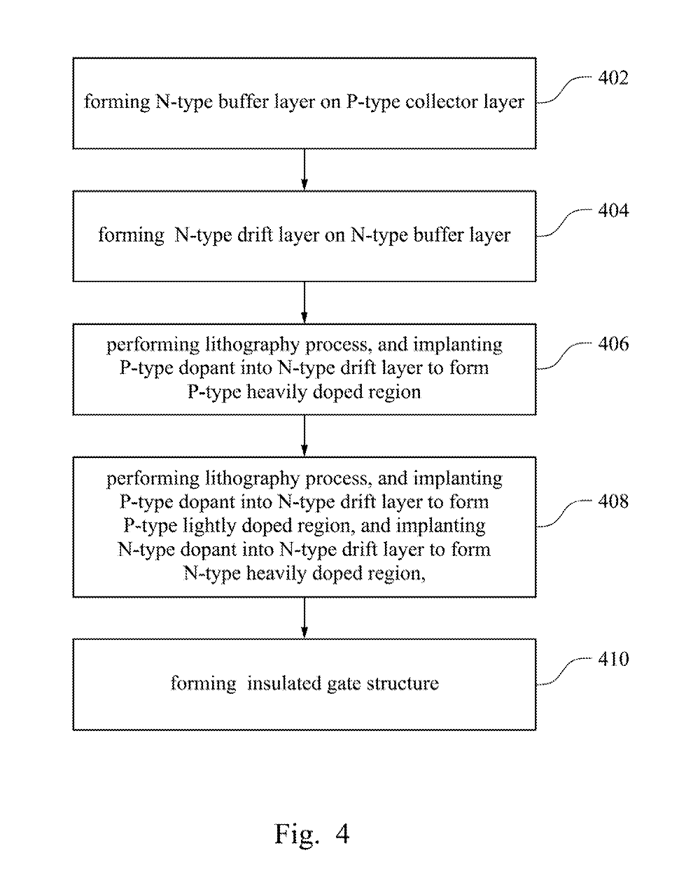

FIG. 4 is a flow chart of a method of manufacturing a semiconductor device according to some embodiments of the present disclosure. For convenience of illustration, the method is described with reference to FIG. 1, but not limited thereto.

In operation 402, the N-type buffer layer 171 is formed on the P-type collector layer 161. For example, the N-type buffer layer 171 is epitaxially grown on the P-type substrate having a dopant concentration consistent with P-type collector layer 161. In another embodiment, the N-type buffer layer 171 can be implanted into P-type substrate having a dopant concentration consistent with P-type collector layer 161.

In operation 404, the N-type drift layer 111 is formed on the N-type buffer layer 171. For example, the N-type drift layer 111 is epitaxially grown on the N-type buffer layer 171. In some embodiments, the N-type buffer layer 171 is omitted, and thus the N-type drift layer 111 is formed on and contacts the P-type collector layer 161.

In operation 406, a lithography process is performed, and a P-type dopant is implanted into a region near a surface of the N-type drift layer 111. As a result, after the lithography process, the region with the P-type dopant is diffused to form the P-type heavily doped region 131.

In operation 408, another lithography process is performed, and a P-type dopant is implanted into a region in the N-type drift layer 111 to form the P-type lightly doped region 151, and an N-type dopant is implanted into a region above the P-type lightly doped region 151, in the N-type drift layer 111, to form the N-type heavily doped region 141.

In various embodiments, the P-type lightly doped region 151 is not formed by implantation, and is instead formed by diffusing the P-type heavily doped region 131. Explained in a different way, the P-type lightly doped region 151 is diffusively formed from the P-type heavily doped region 131.

In operation 410, the insulated gate structure 120 is formed, in which the insulated gate structure 120 contacts the N-type heavily doped region 141 and the P-type lightly doped region 151.

In some embodiments, the insulated gate structure 120 may be formed by following operations. The trench 122 is first formed, and the insulating film 124 is formed over an internal wall surface of the trench 122. Then, the gate electrode 126 is formed in the trench 122. Afterwards, the interlayer dielectric 128 is formed on the gate electrode 126.

In further embodiments, the semiconductor device 100 is an insulated-gate bipolar transistor (IGBT), and the semiconductor device 100 may further include the emitter electrode 180 and the collector electrode 185. The emitter electrode 180 is formed over a part of the surface of the N-type heavily doped regions 141 and 142 and the interlayer dielectric 128. The collector electrode 185 is formed on a back surface of the P-type collector layer 161.

In another embodiments, the method of manufacturing a semiconductor device can start with forming the N-type drift layer 111; for example, an N-type substrate having a dopant concentration consistent with N-type drift layer 111 is provided, so as to form/selectively define the N-type drift layer 111. Then, operations 406-410 are performed as described previously into/on the front side of N-type drift layer 111. An N-type buffer layer 171 is further formed on the back side of the N-type drift layer 111; for example, an N-type dopant is implanted into N-type drift layer 111. Afterwards, P-type collector layer 161 is formed on the back side of the N-type buffer layer 171; for example, a P-type dopant is implanted into the back side of the N-type buffer layer 171. The back side of the N-type drift layer 111 or the N-type buffer layer 171 in aforementioned description is a side opposite to the front side. More specifically, the back side of the N-type drift layer 111 or the N-type buffer layer 171 in aforementioned description is a side opposite to the side where the insulated gate structure be formed. In further embodiments, the step of forming N-type buffer layer 171 can be omitted.

The steps are not necessarily recited in the sequence in which the steps are performed. For example, the method of manufacturing a semiconductor device can start with forming the N-type drift layer 111 and the N-type buffer layer 171. N-type buffer layer 171 can be formed by dopant implantation process accompanying diffusion process. Then, operations 406-410 are performed as described previously into/on the front side of N-type drift layer 111. That is, unless the sequence of the steps is expressly indicated, the sequence of the steps is interchangeable, and all or part of the steps may be simultaneously, partially simultaneously, or sequentially performed.

As is understood by one of ordinary skill in the art, the foregoing embodiments of the present disclosure are illustrative of the present disclosure rather than limiting of the present disclosure. It is intended to cover various modifications and similar arrangements included within the spirit and scope of the appended claims, the scope of which should be accorded with the broadest interpretation so as to encompass all such modifications and similar structures.

1. A semiconductor device comprising:
a first semiconductor layer of a first conductivity type;
an insulated gate structure formed in a trench configuration recessed into the first semiconductor layer;
a first semiconductor region of a second conductivity type formed in the first semiconductor layer;
a second semiconductor region of the first conductivity type formed in the first semiconductor layer, the second semiconductor region contacting the first semiconductor region and the insulated gate structure; and
a lightly doped semiconductor region of the second conductivity type formed in the first semiconductor layer, the second semiconductor region formed on the lightly doped semiconductor region, the lightly doped semiconductor region formed between and contacting the first semiconductor region and the insulated gate structure.

2. The semiconductor device as claimed in claim 1, wherein the lightly doped semiconductor region and the first semiconductor region are individual semiconductor regions, and the lightly doped semiconductor region has dopant concentration lower than that of the first semiconductor region.

3. The semiconductor device as claimed in claim 1, wherein the lightly doped semiconductor region and the first semiconductor region are separately formed by implantation.

4. The semiconductor device as claimed in claim 1, wherein the lightly doped semiconductor region is diffusively formed from the first semiconductor region.

5. The semiconductor device as claimed in claim 1, wherein the lightly doped semiconductor region and the second semiconductor region have substantially same width.

6. The semiconductor device as claimed in claim 1, further comprising:
a third semiconductor region of the second conductivity type formed in the first semiconductor layer, the third semiconductor region contacting a bottom of the insulated gate structure.

7. The semiconductor device as claimed in claim 1, wherein a doping concentration of the lightly doped semiconductor region has a range of approximately 1×10¹³-1×10¹³ 1/cm³.

8. The semiconductor device as claimed in claim 1, further comprising:
a second semiconductor layer of the second conductivity type; and
a third semiconductor layer of the first conductivity type formed between the first semiconductor layer and the second semiconductor layer, the third semiconductor layer having a dopant concentration higher than that of the first semiconductor layer.

9. A semiconductor device comprising:
a P-type collector layer;
an N-type drift layer formed above the P-type collector layer;
an insulated gate structure formed in a trench configuration recessed into the N-type drift layer;
a first P-type heavily doped region formed in the N-type drift layer;
an N-type heavily doped region formed in the N-type drift layer, the N-type heavily doped region contacting the first P-type heavily doped region and the insulated gate structure; and
a P-type lightly doped region formed in the N-type drift layer, the P-type lightly doped region contacting the insulated gate structure, the first P-type heavily doped region and the N-type heavily doped region.

10. The semiconductor device as claimed in claim 9, wherein the P-type lightly doped region and the first P-type heavily doped region are separately formed by implantation.

11. The semiconductor device as claims in claim 9, wherein the P-type lightly doped region is diffusively formed from the first P-type heavily doped region.

12. The semiconductor device as claimed in claim 9, wherein the P-type lightly doped region and the N-type heavily doped region have a substantially same width.

13. The semiconductor device as claimed in claim 9, further comprising:
a second P-type heavily doped region formed in the N-type drift layer, the second P-type heavily doped region contacting a bottom of the insulated gate structure.

14. The semiconductor device as claimed in claim wherein a doping concentration of the P-type lightly doped region has a range of approximately 1×10¹³-1×10¹⁸ 1/cm³.

15. The semiconductor device as claimed in claim 9, further comprising:
an N-type buffer layer formed between the P-type collector layer and the N-type drift layer.

16. A method of manufacturing a semiconductor device, comprising:
forming an N-type drift layer:
forming an insulated gate structure in a trench configuration recessed into be N-type drift layer;
forming a first P-type heavily doped region formed in the N-type drift layer;
forming a P-type lightly doped region in the N-type drift layer, wherein the P-type lightly doped region contacts the insulated gate structure and the first P-type heavily doped region; and
forming an N-type heavily doped region on the P-type lightly doped region in the N-type drift layer, wherein the N-type heavily doped region contacts the first P-type heavily doped region and the insulated gate structure.

17. The method as claimed in claim 16, wherein the first P-type heavily doped region and the P-type lightly doped region are formed by separately implanting P-type dopants into the N-type drift layer.

18. The method as claimed in claim 16, wherein the P-type lightly doped region is formed by diffusing the first P-type heavily doped region.

19. The method as claimed in claim 16, further comprising:
forming an N-type buffer layer on a first side of the N-type drift layer, wherein the first side of the N-type drift layer is opposite to a side of the N-type drift layer where the insulated gate structure herein;
forming a P-type collector layer on a first side of the N-type buffer layer, wherein the first side of the N-type buffer layer is opposite to a side of the N-type drift er where the insulated gate structure therein.

20. The method as claimed in claim 16, wherein the N-drift layer is formed above a P-type substrate.
